(19) United States
(12) Patent Application Publication
(10) Pub. No.: US 2008/0003701 A1
(43) Pub. Date: Jan. 3, 2008

(54) NON-VIA METHOD OF CONNECTING MAGNETOELECTRIC ELEMENTS WITH CONDUCTIVE LINE

(75) Inventors: Young-Shying Chen, Hsinchu County (TW); Wei-Chuan Chen, Taipei County (TW); Ming-Jer Kao, Tainan City (TW)

Correspondence Address: QUINTERO LAW OFFICE, PC, 2210 MAIN STREET, SUITE 200, SANTA MONICA, CA, 90405, US

(73) Assignee: INDUSTRIAL TECHNOLOGY RESEARCH INSTITUTE, HSINCHU (TW)

(21) Appl. No.: 11/781,163

(22) Filed: Jul. 20, 2007

Related U.S. Application Data
(63) Continuation-in-part of application No. 11/154,632, filed on Jun. 17, 2005, now abandoned.

(30) Foreign Application Priority Data
Dec. 31, 2004 (TW) TW93141732

(51) Int. Cl. H01L 21/4763; H01L 21/00

(52) U.S. Cl. 438/3; 438/618; 257/E21.001; 257/E21.495

(57) ABSTRACT

A non-via method of connecting a magnetoelectric element with a conductive line is provided. A magnetoelectric element is formed on a substrate. Spacers are formed on side walls of the magnetoelectric element. A first dielectric layer is deposited over the substrate and the magnetoelectric element. The first dielectric layer is planarized to a level above the magnetoelectric element. A second dielectric layer is deposited over the first dielectric layer. The first and second dielectric layers are etched to form a trench, exposing an upper surface of the magnetoelectric element. A conductive material layer is filled into the trench to form a conductive line on the magnetoelectric element.

This application is a Continuation-In-Part of pending U.S. patent application Ser. No. 11/154,632, filed Jun. 17, 2005, and entitled “Non-via method of connecting magnetoelectric elements with conductive line”.

### BACKGROUND OF THE INVENTION

1. Field of the Invention

The present invention relates to a non-via method, and more specifically to a non-via method of connecting a magnetoelectric element with a conductive line.

2. Description of the Related Art

Magnetoresistive random access memory (MRAM) is an increasingly popular new generation memory, following SRAM, DRAM, and flash memory, due to its non-volatility, high integration, high readout speed, anti-radiation, and high compatibility with CMOS fabrication.

MRAM structure comprises upper and lower conductive metal layers in X and Y-orientations, respectively, and a magnetoelectric element disposed therebetween such as giant magnetoresistance (GMR), magnetic tunneling junction (MTJ), or tunneling magnetoresistance (TMR), wherein the conductive metal layers are bit line and word line, respectively.

MTJ is a stacked structure of multiple layers of magnetic metal material comprising a free layer, a tunnel barrier layer, a pinned layer, and an anti-ferromagnetic layer, wherein the free layer and pinned layer, preferably, comprise ferromagnetic materials. The pinned layer exhibits a fixed magnetization orientation due to interactions with the anti-ferromagnetic layer. The free layer, however, exhibits an altered magnetization orientation due to various induced magnetic fields from bit line and word line. Resistance of MTJ can thus be altered by presentation of parallel or perpendicular magnetization orientations between the free layer and pinned layer. When current is applied to MTJ, data can be read out by voltage type to determine “1” or “0” memory state.

With reduction of memory size, via processes connecting MTJ with word line have suffered from problems such as alignment shift in development and control of etching depth, hindering progress of size reduction. Additionally, read-in current has also approached load-bearing limitations of metal line, producing electron migration.

Related non-via methods of connecting a MTJ with a word line are described in the following. For example, as disclosed in U.S. Pat. No. 6,744,608, a conductive or dielectric hard mask layer is firstly formed over a MTJ. A dielectric layer overlying the MTJ is then planarized by chemical mechanical polishing (CMP) until the hard mask layer is exposed. The conductive hard mask layer can remain on the MTJ surface. The dielectric layer, however, must be removed by additional steps. A word line fabrication then proceeds. The method solves alignment shift in development and provides precise control of etching depth, high magnetic field efficiency, and low read-in current due to direct connection between the word line and the MTJ.

Nevertheless, the related method cannot precisely control the depth of polishing to the hard mask layer. Over-polishing to the MTJ usually occurs, because various control parameters, such as polishing pad, polishing solution, and polishing end point, must be considered simultaneously. Even when the dielectric layer is polished to near the upper surface of the hard mask layer, polishing program or apparatus must further be adjusted to ensure formation of a smooth dielectric layer plane, avoiding dishing. Further, with requirement for estimation of attrition of polishing pad, alteration of polishing solution, and control of polishing end point, such techniques become more complicated.

As disclosed in U.S. Pat. No. 6,783,995, a sacrificial cap layer or spacers are formed over a MTJ or on side walls thereof to protect the MTJ from etching. After removing the sacrificial cap layer, a metal line fabrication proceeds.

### BRIEF SUMMARY OF THE INVENTION

In one embodiment, a non-via method of connecting a magnetoelectric element with a conductive line is provided. A magnetoelectric element is formed on a substrate. Spacers are formed on side walls of the magnetoelectric element. A first dielectric layer is deposited over the substrate and the magnetoelectric element. The first dielectric layer is planarized to a level above the magnetoelectric element. A second dielectric layer is deposited over the first dielectric layer. The first and second dielectric layers are etched to form a trench, exposing an upper surface of the magnetoelectric element. A conductive material layer is filled into the trench to form a conductive line on the magnetoelectric element.

The non-via method solves alignment shift in development and provides precise control of etching depth, making it suitable for use in size reduction of magnetoelectric elements.

The non-via method also reduces read-in current and power consumption of MRAM during the read-in period, because the word line is directly pasted on the magnetoelectric element, increasing magnetic field efficiency.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a flow chart of a non-via method in an embodiment of the invention.

FIGS. 2A˜2F are cross sections of a method of connecting a magnetoelectric element with a conductive line in an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

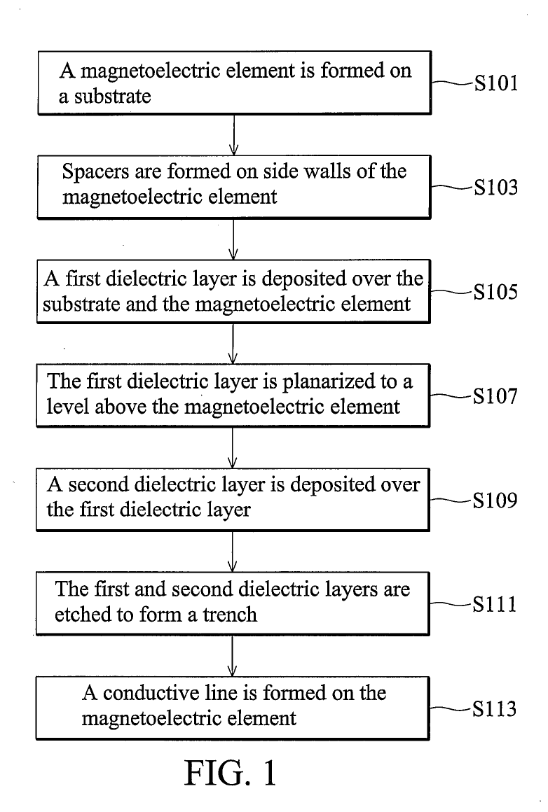

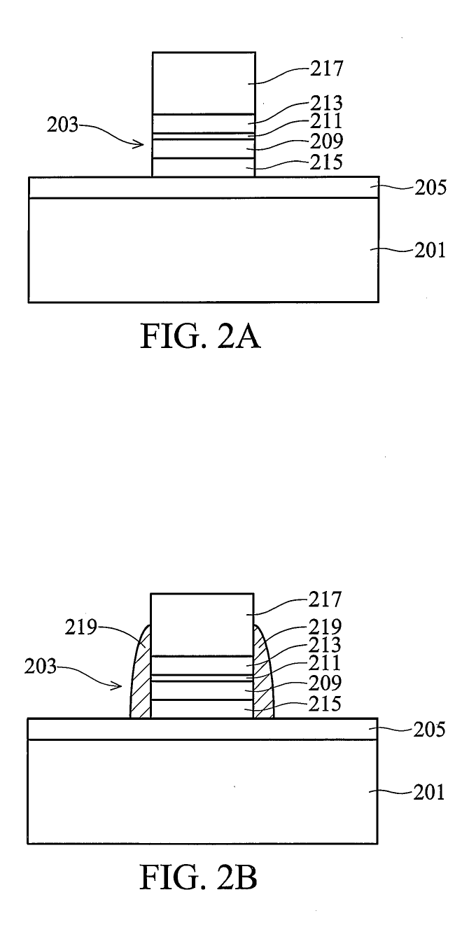

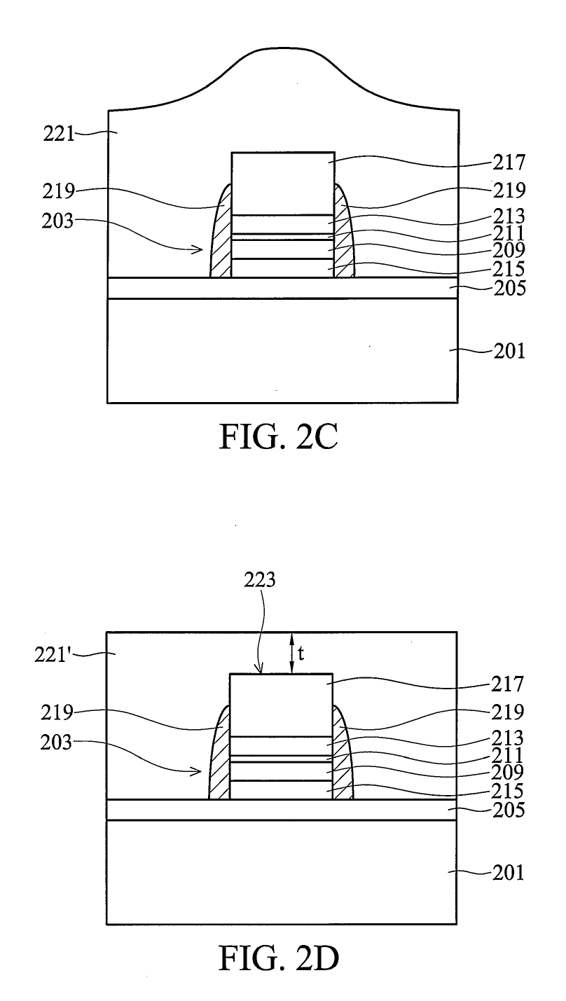

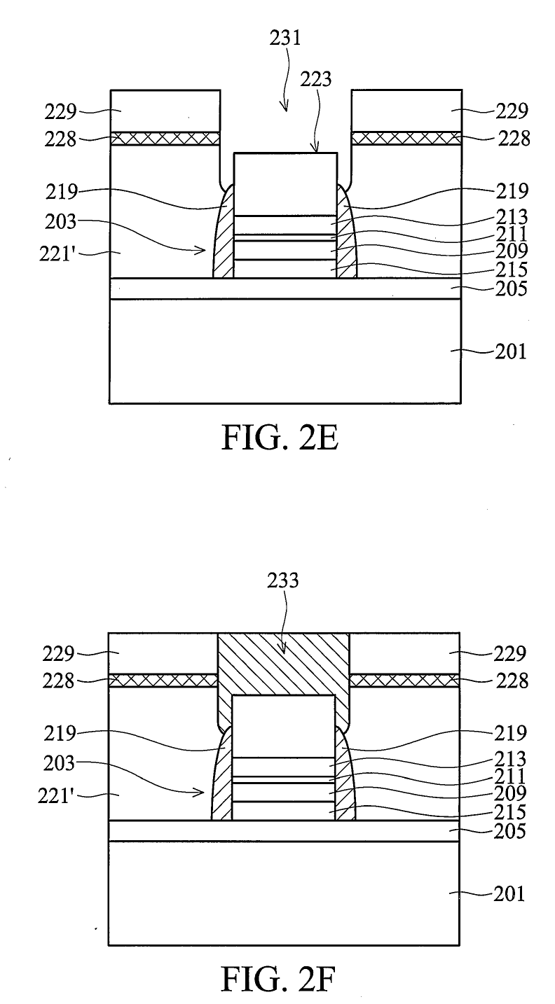

Although the invention is described by way of the following example regarding a non-via method of connecting a conductive line with a MTJ element, the invention is not limited thereto. The embodiment is illustrated by FIG. 1 and FIG. 2A˜2F.

Referring to FIG. 1 and FIG. 2A, a MTJ element 203 is formed on a substrate 201 in step S101. A conductive line 205 is formed on or in the substrate 201, for example, a Cu or Al conductive line, and the MTJ element 203 is formed thereon. The substrate 201 can further comprise other semiconductor devices such as CMOS connecting the MTJ element 203 with the conductor line 205. In order to simplify the drawing, the semiconductor devices are not illustrated therein. The MTJ element 203 is a stacked structure of multiple layers mainly comprising a pinned layer 209, a tunnel barrier layer 211, and a free layer 213. The pinned layer 209 and the free layer 213 are magnetic materials and the tunnel barrier layer 211 is disposed therebetween.

The pinned layer 209 and the free layer 213 are ferromagnetic materials such as Fe, Co, Ni, or combinations thereof. The tunnel barrier layer 211 may be Al₂O₃ or MgO. Magnetization orientation of the pinned layer 209 is fixed and its coercive field (Hc) is increased by an anti-ferromagnetic layer 215 with ferromagnetic-anti-ferromagnetic exchange coupling interaction to stabilize magnetic moment. Magnetoelectric elements provided by the invention are not limited to such MTJ elements and may alternatively comprise MTJ including other structures or layers or other element types.

The top layer of the MTJ element 203 comprises a hard mask layer 217, for example, a conductive hard mask layer such as Ta, Ti, Cr, TaN, or TiN. The hard mask layer 217 has a thickness of about 400˜600 Å. The completed MTJ element structure is formed by deposition, development, and etching. The hard mask layer 217 is used as a hard mask of the MTJ element 203 during etching.

Next, referring to FIG. 1 and FIG. 2B, spacers 219 are formed on side walls of the MTJ element 203 and the hard mask layer 217 in step S103. The spacers 219 are formed by, for example, conformal material layer deposition over the substrate 201 and the MTJ element 203 comprising the hard mask layer 217 at the top layer thereof. Spacers 219 are formed by anisotropic etching to protect the side walls of the MTJ element 203. The spacers 219 comprise nitride such as silicon nitride or silicon nitride grown at low temperature.

Next, referring to FIG. 1 and FIG. 2C, a first dielectric layer 221 is deposited over the substrate 201 and the MTJ element 203 by related deposition methods such as chemical vapor deposition, physical vapor deposition, or spin coating, in step S105. The first dielectric layer 221 has an etching selectivity to the hard mask layer 217 and the spacers 219. Thus, the hard mask layer 217 and the spacers 219 protect the MTJ element 203 during etching. To avoid deteriorated magnetoelectrical performance of the MTJ element 203 at high temperatures, the first dielectric layer 221 is an oxide material, such as silicon oxide, grown at low temperature.

Next, referring to FIG. 1 and FIG. 2D, the first dielectric layer 221 is planarized to a level t above the upper surface 223 of the hard mask layer 217 at the top of the MTJ element 203 to form a first dielectric layer structure 221′ in step S107. The planarization can be performed by related chemical mechanical polishing (CMP). The polishing conditions are easily controlled, because determination of the level t above the upper surface 223 of the hard mask layer 217 can be rough, without precise measurement. The level t is less than 1,000 Å.

Next, referring to FIG. 1 and FIG. 2E, a second dielectric layer 229 is deposited over the first dielectric layer 221′ in step S109. The second dielectric layer 229 may comprise fluorinated silicate glass (FSG), un-doped silicate glass (USG), low K material, or black diamond. The second dielectric layer 229 has a thickness of about 500˜3,500 Å. A trench 231 is then formed through the second dielectric layer 229 and the first dielectric layer 221′ in step S111 by development and etching such as dry etching, exposing the upper surface 223 of the MTJ element 203. Tolerance of alignment shift in development is increased due to the spacers 219 used as an etching stop layer. The trench 231 may be wider than the MTJ element 203.

Next, a conductive material layer, such as Cu, is filled into the trench 231 in step S113 to form a conductive line 233 on the MTJ element 203, as shown in FIG. 2F.

Damascene processes suitable for use in the invention are not limited to those shown in FIG. 2E˜2F, with any proper modifications and similar arrangements thereof allowable. For example, addition of an etching stop layer 228 (as shown in FIGS. 2E and 2F) such as silicon nitride or silicon carbide, diffusion barrier layer such as Ti, Ta, W, or nitride thereof, or seed layer, or replacement of MTJ by giant magnetoresistance (GMR).

The spacers and hard mask layer provided by the invention can be used as barrier layers to protect the MTJ element during the dielectric layer etching and trench etching in metal damascene process.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A non-via method of connecting a magnetoelectric element with a conductive line, comprising:
forming a magnetoelectric element having a top layer on a substrate;
forming spacers on side walls of the magnetoelectric element;
depositing a first dielectric layer over the substrate and the magnetoelectric element;
planarizing the first dielectric layer to a level above the magnetoelectric element;
depositing a second dielectric layer over the first dielectric layer;
etching the first and second dielectric layers to form a trench, exposing an upper surface of the magnetoelectric element;
filling a conductive material layer into the trench to form a conductive line on the magnetoelectric element.

2. The non-via method as claimed in claim 1, wherein the magnetoelectric element comprises a magnetic tunnel junction (MTJ) element.

3. The non-via method as claimed in claim 1, wherein the top layer of the magnetoelectric element comprises a hard mask layer.

4. The non-via method as claimed in claim 3, wherein the hard mask layer is a conductive layer.

5. The non-via method as claimed in claim 3, wherein the hard mask layer comprises Ta, Ti, Cr, TaN, or TiN.

6. The non-via method as claimed in claim 3, wherein the hard mask layer has a thickness of about 400˜600 Å.

7. The non-via method as claimed in claim 1, wherein the spacers comprise silicon nitride grown at low temperature.

8. The non-via method as claimed in claim 1, wherein the first dielectric layer is planarized by chemical mechanical polishing (CMP).

9. The non-via method as claimed in claim 1, wherein the level above the magnetoelectric element is less than 1,000 Å.

10. The non-via method as claimed in claim 1, wherein the second dielectric layer has a thickness of about 500˜3,500 Å.

11. The non-via method as claimed in claim 1, wherein the first and second dielectric layers are etched by dry etching.

12. The non-via method as claimed in claim 1, wherein the first and second dielectric layers comprise oxide.

13. The non-via method as claimed in claim 1, wherein the conductive material layer comprises Cu.
